(19) United States
(12) Patent Application Publication
(10) Pub. No.: US 2019/0019775 A1
(43) Pub. Date: Jan. 17, 2019

(54) SEMICONDUCTOR DEVICE AND METHOD OF MANUFACTURE THEREOF

(71) Applicant: TOSHIBA MEMORY CORPORATION, Tokyo (JP)

(72) Inventors: Takuma KAWAMURA, Sumida Tokyo (JP); Toyokazu EGUCHI, Inagi Tokyo (JP)

(21) Appl. No.: 16/042,783

(22) Filed: Jul. 23, 2018

Related U.S. Application Data
(62) Division of application No. 15/448,605, filed on Mar. 3, 2017, now abandoned.

(30) Foreign Application Priority Data
Mar. 24, 2016 (JP) 2016-060828

(51) Int. Cl. H01L 23/00; H01L 23/498

(52) U.S. Cl. CPC H01L 24/17; H01L 2924/1443; H01L 24/06; H01L 24/13; H01L 24/81; H01L 23/49811; H01L 2924/05042; H01L 2924/0133; H01L 2924/0132; H01L 2924/01079; H01L 2924/01029; H01L 2924/01022; H01L 2224/81815; H01L 2224/81191; H01L 2224/16157; H01L 2224/16013; H01L 2224/14131; H01L 2224/13005; H01L 2924/07025; H01L 2924/10161; H01L 2924/1436; H01L 2924/1438; H01L 2924/35; H01L 23/49838

(57) ABSTRACT

A semiconductor device includes a board having a solder resist layer with first and second openings on a first surface, and a first electrode on the first surface, a portion thereof exposed in the first opening and electrically connected to the board. A second electrode is located on the first surface having a portion exposed in the second opening and electrically connected to the board. A portion of the second electrode is covered by the solder resist layer. A first solder bump is on the first electrode and covers a side surface. A second solder bump is on the second electrode. A semiconductor chip has a first region and a second region facing the first surface. A third electrode is in the first region and electrically connected to the first solder bump. A fourth electrode is in the second region and electrically connected to the second solder bump.

### CROSS-REFERENCE TO RELATED APPLICATIONS

This application is a division of U.S. patent application Ser. No. 15/448,605, filed on Mar. 3, 2017, which claims the benefit of priority from Japanese Patent Application No. 2016-060828, filed Mar. 24, 2016, the entire contents of each. of which are incorporated herein by reference.

### FIELD

Embodiments described herein relate generally to a semiconductor device.

### BACKGROUND

A solid state drive (SSD) in which a controller and a nonvolatile memory are mounted on a board is known. The controller and the nonvolatile memory are bonded to the board by, for example, solder bumps.

### DESCRIPTION OF THE DRAWINGS

FIG. 1 illustrates a semiconductor device according to first to third embodiments.

FIG. 2 is a diagram illustrating an example of the system configuration of the semiconductor device according to the first to third embodiments.

FIG. 3 is a cross-sectional view illustrating the configuration of the semiconductor device according to the first embodiment.

FIG. 4 is an enlarged view of a region A illustrated in FIG. 3.

FIG. 5 is a plan view illustrating an arrangement of solder bumps of the semiconductor device according to the first to third embodiments.

FIGS. 6A and 6B are enlarged views illustrating the solder bumps of the semiconductor device according to the first embodiment.

FIGS. 7A and 7B are cross-sectional views illustrating a method of forming the solder bumps according to the first embodiment.

FIGS. 8A to 8C are enlarged views of the solder bumps of a semiconductor device according to a comparative example.

FIG. 9 is an enlarged view illustrating the solder bump of the semiconductor device according to the second. embodiment.

FIGS. 10A to 10C are enlarged views illustrating the land of the semiconductor device according to the third embodiment.

### DETAILED DESCRIPTION

Embodiments provide a semiconductor device with excellent mounting reliability.

In general, according to one embodiment, a semiconductor device includes a board having a first surface and a solder resist layer on the first surface. The solder resist layer has a first opening and a second opening. A first electrode is on the first surface and has a side surface exposed in the first opening. The first electrode is electrically connected to the hoard. A second electrode, having an outer perimeter, is on the first surface. At least a portion of the second electrode is exposed through the second opening. The second electrode is electrically connected to the board, and at least a portion of the outer perimeter of the second electrode is covered by the solder resist layer. A first solder bump is on the first electrode. The first solder bump covers the side surface of the first electrode. A second solder bump is on the second electrode, and a semiconductor chip has a second surface facing the first surface. The second surface has a first region and a second region. A third electrode located in the first region of the semiconductor chip is electrically connected to the first solder bump, and a fourth electrode is located in the second region of the semiconductor chip and is electrically connected to the second solder bump.

Hereinafter, exemplary embodiments of the present disclosure will be described with reference to the drawings.

### First Embodiment

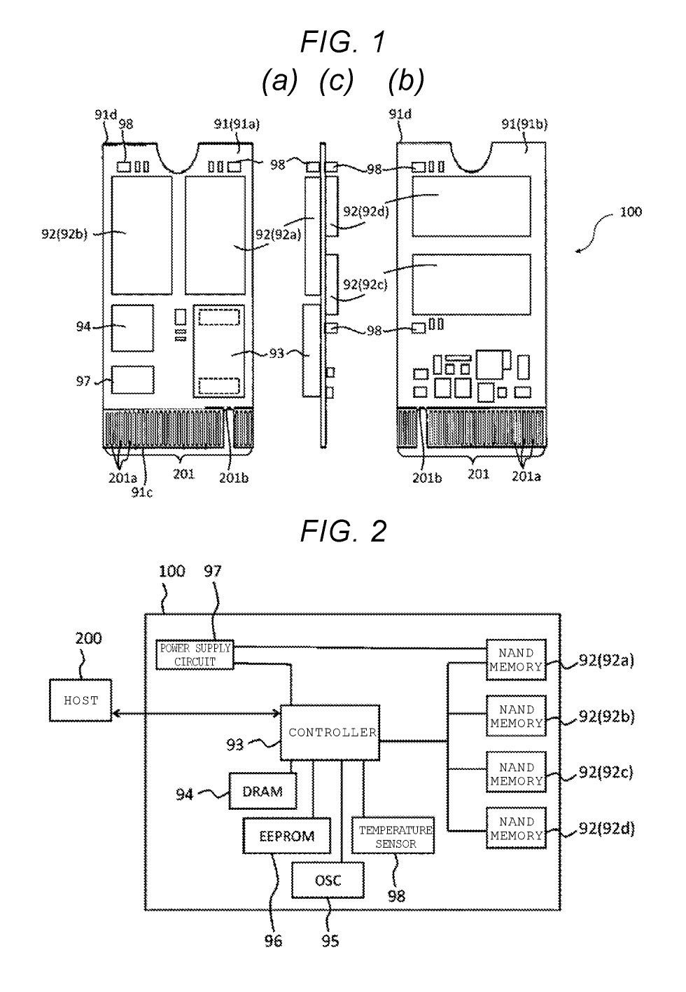

A semiconductor device according to a first embodiment will be described with reference to FIG. 1 to FIG. 8C. In the following description of the drawing figures, the same elements are denoted with the same reference numerals where present in different drawing figures. Here, in the drawing figures, the relationship and the ratio between the thickness and the planar dimensions, and the like may be different from those of an actual device, and are schematic.

FIG. 1 and FIG. 2 illustrate an example of a semiconductor device 100 according to the present embodiment. FIG. 1 depicts a plan view (a) of the semiconductor device 100, a bottom view (b) of the semiconductor device 100, and a side view (c) of the semiconductor device 100. FIG. 2 illustrates an example of a system configuration of the semiconductor device 100. As illustrated in FIG. 2, the semiconductor device 100 is connected to a host 200.

As illustrated in FIG. 1 and FIG. 2, the semiconductor device 100 includes, for example, a mounting board 91, nonvolatile memories 92, a controller 93, a volatile memory 94 that can operate at a higher speed than that of the nonvolatile memory 92, an oscillator (OSC) 95, an electrically erasable and programmable ROM (EEPROM) 96, a power supply circuit 97, temperature sensors 98, and other electronic components such as a resistor and a capacitor.

The nonvolatile memory 92 is, for example, a NAND type flash memory (hereinafter, referred to as a NAND memory). In the following description, although the nonvolatile memory 92 will be described as “NAND memory 92”, the nonvolatile memory 92 is not limited thereto, and may be another type of nonvolatile memory such as a magnetoresistive random access memory (MRAM).

The volatile memory 94 is, for example, a dynamic random access memory (DRAM). In the following description, although the volatile memory 94 will be described as “DRAM 94”, the volatile memory 94 is not limited thereto, and may be another type of volatile memory.

The NAND memory 92, the controller 93, and the power supply circuit 97 according to the present embodiment are each a semiconductor package which is an electronic component. For example, the semiconductor package of the NAND memory 92 is a system in package (SiP) type module, and a plurality of semiconductor chips are sealed within one package. On the other hand, the power supply circuit 97 is a chip size package (CSP) type module, and includes one semiconductor chip.

The mounting board 91 is a substantially rectangular circuit board that is made of, for example, a material such as glass epoxy resin, and the size thereof dictates the external dimensions of the semiconductor device 100. The mounting board 91 has a first surface 91a and a second surface 91b positioned on the opposite side of the mounting board 91 from the first surface 91a. In this disclosure, the surfaces other than the first surface 91a and the second surface 91b among the surfaces that configure the mounting board 91 are defined as “side surfaces”. In the semiconductor device 100, the first surface 91a and the second surface 91b are component mounting surfaces on which the NAND memory 92, the controller 93, the DRAM 94, the oscillator 95, the EEPROM 96, the power supply circuit 97, the temperature sensor 98, and other electronic components such as a resistor and a capacitor are mounted.

As illustrated in FIG. 1, the mounting board 91 has a first edge portion 91c and a second edge portion 91d positioned on the opposite side of the mounting board 91 from the first edge portion 91c. In the vicinity of the first edge portion 91c, an interface unit 201 (a board interface portion, a terminal portion, and a connection portion) are provided. The interface unit 201 includes, for example, a plurality of connection terminals 201a (metal terminals). The interface unit 201 is electrically connectable to the host 200. The interface unit 201 is provided such that the semiconductor device 100 can transmit and receive signals (control signals and data signals) to and from the host 200.

The interface unit 201 is an interface that is based on, for example, the PCI-express (PCIe) standard. That is, high-speed signals (high-speed differential signals) based on the PCIe standard are transmitted and received between the interface unit 201 and the host 200. The semiconductor device 100 is supplied with power via the interface unit 201 from the host 200.

The interface unit 201 may be based on another standard such as the serial attached SCSI (SAS) standard, the serial ATA (SATA) standard, the non-volatile memory express (NVMe) standard, or the like.

The power supply circuit 97 is, for example, a DC-DC converter, and it generates a predetermined voltage for operating the NAND memory 92, the controller 93, and the like using the power supplied from the host 200. Preferably, the power supply circuit 97 is installed in the vicinity of the interface unit 201 in order to prevent loss of the power supplied from the host 200.

The controller 93 controls operations of the NAND memory 92. That is, the controller 93 controls writing, reading, and deleting of data to and from the NAND memory 92.

As described above, the DRAM 94 is an example of a volatile memory, and is used for storing management information of the NAND memory 92, caching data of the NAND memory 92, or the like. The oscillator 95 supplies an operation signal having a predetermined frequency to the controller 93. The EEPROM 96 stores control programs and the like as fixed information.

The temperature sensor 98 monitors the temperature of the controller 93, for example. Although the temperature sensor 98 is mounted, for example, in the vicinity of the controller 93 on the mounting board 91, the position of the temperature sensor 98 is not limited thereto. The temperature sensor 98 is not necessarily provided on the mounting board 91, and may be provided as a function of the controller 93.

In the present embodiment, the number of the NAND memories 92, the mounting positions of the NAND memories 92, and the like are not limited to the drawings. In the present embodiment, although an example in which two NAND memories (92a and 92b) are mounted on the first surface 91a of the mounting board 91 and two NAND memories 92, (92c and 92d) are mounted on the second surface 91b of the mounting board 91 is illustrated, the number of the NAND memories 92 is not limited thereto. For example, all components to be mounted on the mounting board 91, including NAND memories 92, may be mounted only on the first surface 91a.

Next, a connection portion between the power supply circuit 97 and the mounting board 91 will be described.

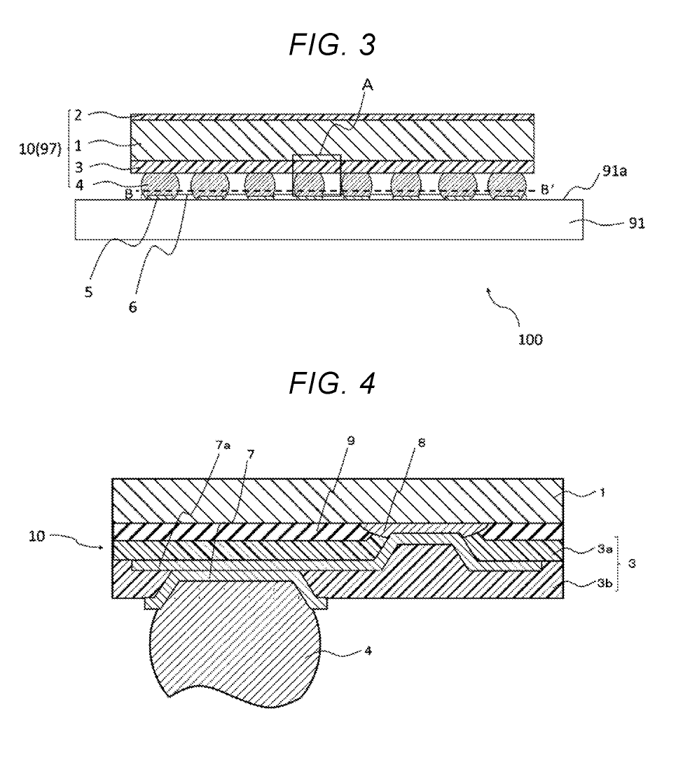

FIG. 3 is a cross-sectional view illustrating a configuration of the semiconductor chip of the power supply circuit 97 according to the present embodiment. FIG. 4 is an enlarged view of a region A illustrated in FIG. 3. As illustrated in FIGS. 3 and 4, the semiconductor chip comprising the power supply circuit 97 is bonded to the first surface 91a of the mounting board 91 by a plurality of solder bumps 4.

Next, the configuration of the power supply circuit 97 will be described. The power supply circuit 97 includes a semiconductor chip 10, for example, having a package structure known as a chip size package (CSP).

As illustrated in FIGS. 3 and 4, the semiconductor chip 10 (power supply circuit 97) includes a semiconductor substrate 1, a back side coating (BSC) film 2 positioned on the upper surface of the semiconductor substrate 1, a polyimide layer 3 positioned on the lower surface of the semiconductor substrate 1, a metal portion 8, and a film 9. The semiconductor substrate 1 includes a semiconductor layer, an insulating film, a conductive film, a contact, and the like (not illustrated). The lower surface of the semiconductor substrate 1 faces the first surface 91a of the mounting board 91.

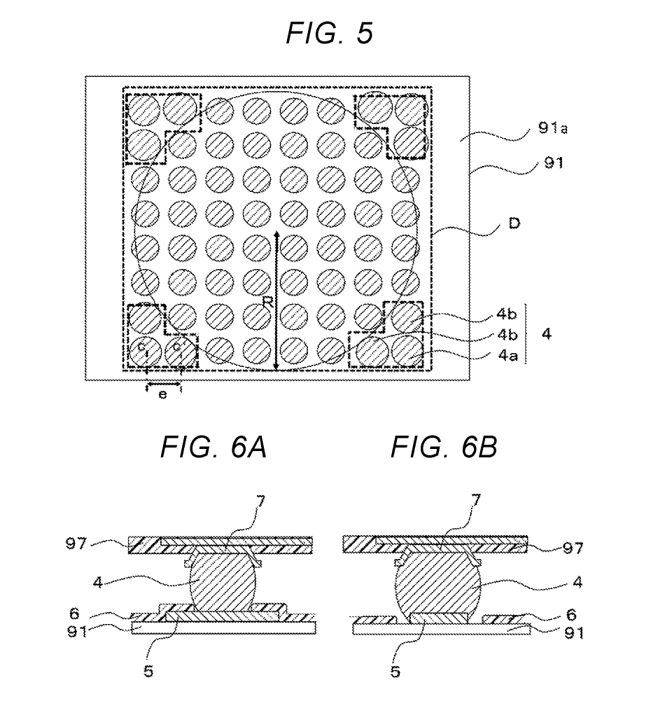

The semiconductor substrate 1 has, for example, a rectangular shape with four corners (FIG. 5). The semiconductor substrate 1 is formed using silicon or the like, but the material is not limited thereto. Further, the BSC film 2 is not necessarily provided.

As illustrated in FIG. 4, the polyimide layer 3 includes a first polyimide layer 3a and a second polyimide layer 3b, and a redistribution layer (RDL) 7a such as Cu is provided between the first and second polyimide layers 3a and 3b. Electrodes 7 that partially protrude from the polyimide layer 3 are provided at connection portions between the redistribution layer 7a and the solder bumps 4. The semiconductor substrate 1 includes a metal portion 8 such as A1, as a connection portion between the semiconductor substrate 1 and the redistribution layer 7a. That is, the solder bump 4 is electrically connected to the semiconductor substrate 1 through the electrode 7, the redistribution layer 7a, and the metal portion 8. Further, the semiconductor substrate 1 includes a film 9 such as SiN or the like. Although a boundary between the first and second polyimide layers 3a and 3b is illustrated in FIG. 4, the first and second polyimide lavers 3a and 3b are made of the same material, and there may be no material boundary therebetween. For example, the redistribution layer 7a is made of TiCu, and the electrodes 7 are made of TiCuAu. However, the materials of the redistribution layer 7a and the electrodes 7 are not limited thereto.

On the other hand, on the first surface 91a of the mounting board 91, a plurality of lands 5 as electrodes, and a solder resist layer 6 that has openings at the positions of the plurality of lands 5 and covers the first Surface 91a, are provided. The lands 5 are electrically connected to a wiring layer (not illustrated) in the mounting board 91. A plurality of solder bumps 4 are positioned between the lands 5 and the polyimide layer 3 of the semiconductor chip 10. That is, the semiconductor chip 10 is electrically connected to the mounting board 91 by the solder bumps 4. The lands 5 are formed using, for example, a material containing copper (Cu) or an alloy of copper (Cu).

Next, the arrangement of the solder bumps 4 on the first surface 91a when mounting the semiconductor chip 10 on the first surface 91a of the mounting board 91 will be described with reference to FIG. 5. FIG. 5 is a plan view illustrating the first surface 91a of the mounting board 91 of the semiconductor device 100 of FIG. 3 taken along line B-B′. The mounting region D on which the semiconductor chip 10 is mounted is illustrated by an outer broken line. FIG. 5 illustrates a portion of the first surface 91a.

The semiconductor chip 10 according to the present embodiment is mounted on the first surface 91a of the mounting board 91, for example, by 8×8 (64) solder bumps 4 arranged in a lattice pattern. Here, the lattice pattern means that the solder bumps 4 and the adjacent solder bumps 4 are regularly arranged alone substantially straight lines. As illustrated in FIG. 5, the pitch width e between the center C or an arbitrary solder bump 4 and the center C′ of the adjacent solder bump 4 is, for example, 0.4 mm. This pitch width is narrower than the pitch width in other electronic components such as the NAND memory 92 or the controller 93.

In the present embodiment, the solder bumps 4 of the semiconductor chip 10 have solder structures including a solder mask defined (SMD) structure and a non-SMD structure. The solder bump 4 with the SMD structure is referred to as “SMD”, the solder bump 4 with the NSMD structure is referred to as “NSMD”, and the same is true of the following description. All the solder bumps 4 of the NAND memory 92, the controller 93, or the like include, for example, the NSMDs.

Hereinafter, cross-sectional views of the SMD and the NSMD used in the present embodiment and characteristics of the SMD and the NSMD will be described.

FIG. 6A. illustrates the cross-sectional view of the SMD, and FIG. 6B illustrates the cross-sectional view of the NSMD. FIGS. 6A and 6B are cross-sectional views illustrating a portion of the mounting board 91 and a portion of the semiconductor chip 10.

As illustrated in FIG. 6A, in the SMD, the land 5 is formed on the mounting board 91. The solder resist layer 6 is formed on the lands 5 so as to cover the edge portions of the lands 5. The solder bumps 4 are formed in he opening of the solder resist layer 6 on the lands 5 so as to connect the electrodes 7 of the semiconductor chip 10 and the lands 5 on the mounting board 91.

As illustrated in FIG. 6B, in the NSMD, the land 5 is formed on the mounting board 91, and the solder resist layer 6 is formed at a predetermined distance from the land 5. The solder bumps 4 are formed on the lands 5 so as to cover the side surfaces of the lands 5 that face the solder resist layer 6, and the electrodes 7 of the semiconductor chip 10 are electrically connected to the lands 5 on the mounting board 91.

In practice, the land 5 has a substantially circular shape in a plan view, and it is connected to the wiring provided on the mounting board 91. In the SMD, the outer circumferential edge portions of the land 5 are covered with the solder resist layer 6 formed on the entire first surface 91a of the mounting board 91, and in the NSMD, the circumferential wail of the openings of the solder resist layer 6 are formed at a distance from the land 5. That is, the openings of the solder resist layer 6 have a substantially circular shape.

Although not illustrated, electrical wiring is connected to each of the lands 5, and the lands 5 are electrically connected to connectors (not illustrated) of the mounting board 91 and other electronic components, other electronic devices, or the like mounted on the mounting board 91 by the electrical wiring.

In the SMD, the cross-sectional area (particularly, the maximum cross-sectional area) of the solder bump 4 in the cross-section (cross-section B-B′ in FIG. 3) parallel to the plane direction (horizontal direction) of the first surface 91a of the mounting board 91 is small. For this reason, in the SMD, there is an advantage that a solder bridge between the solder bump 4 and the adjacent solder bump 4 infrequently occur. The fact that the solder bridge between the solder bump 4 and the adjacent solder bump 4 infrequently occurs means that it is possible to reduce the width between the solder bumps 4, and thus this is useful for arranging the solder bumps 4 at a higher density. A solder bridge is a state where one solder bump 4 is coupled and electrically connected to another solder bump 4. However, in the SMD, the solder bump 4 is weak against shear stress, and there is a disadvantage that a crack in the solder bump 4 tends to occur. This shear stress is a stress that is generated from a difference in thermal expansion between the mounting board 91 and the semiconductor chip 10 due to, for example, a temperature change or the like. Thus, the shear stress is small at the center portion of the semiconductor chip 10, and the shear stress is large at the edge portion of the semiconductor chip 10.

On the other hand, in the NSMD, since the diameter of the solder bump 4 in the cross-section in the direction parallel to the mounting board 91 is large, the bridge is more likely to occur. In contrast, since the bonding between the solder bump 4 and the land 5 on the mounting board 91 is strong and the diameter of the solder bump 4 is large, there is an advantage that the solder bump 4 is strong against shear stress.

In the plan view of FIG. 5, among the solder bumps 4 in the mounting region D, the solder bumps 4a at the four corners of the mounting region D and the solder bumps 4b that are adjacent to the solder bumps 4a at the four corners and positioned at the outermost circumferential portions of the solder bumps 4 arranged in a lattice pattern are, for example, NSMDs. The other solder bumps 4 are, for example, SMDs.

Since the SMDs and the NSMDs are arranged as illustrated in FIG. 5, NSMDs having a strong tolerance to shear stress are used for the edge portions where the shear stress is large (particularly, the four corners of the solder bumps 4 in the mounting region D), and SMDs are used for the other solder bumps 4. Therefore, it is possible to minimize the number of the solder bumps 4 configured as NSMDs to a minimum. Thus, the semiconductor device 100 according to the present embodiment has a strong tolerance to the shear stress, and thus it is possible to reduce the risk of occurrence of the solder bridge. In the case of other electronic components other than the power supply circuit 97, since the pitch width between the solder bumps 4 is wider than the pitch width in the power supply circuit 97, there is no concern that a solder bridge between the solder bumps 4 will occur, and thus NSMDs can be used for all the solder bumps 4 for these components.

The number of the solder bumps 4a and 4b configured as NSMDs is not limited. For example, NSMDs are formed at positions outside the range of an arbitrary distance R from the center of the mounting region D of the first surface 91a of the mounting board 91. In the present embodiment, the arbitrary distance R is approximately 1.70 mm. The distance R can be appropriately selected depending on the number of the solder bumps 4 in the mounting region D or the pitch width. The solder bumps 4a and 4b that are positioned at positions outside the range of an arbitrary distance R from the center of the mounting region D may be expressed as being positioned at the corner portions of the mounting board 91.

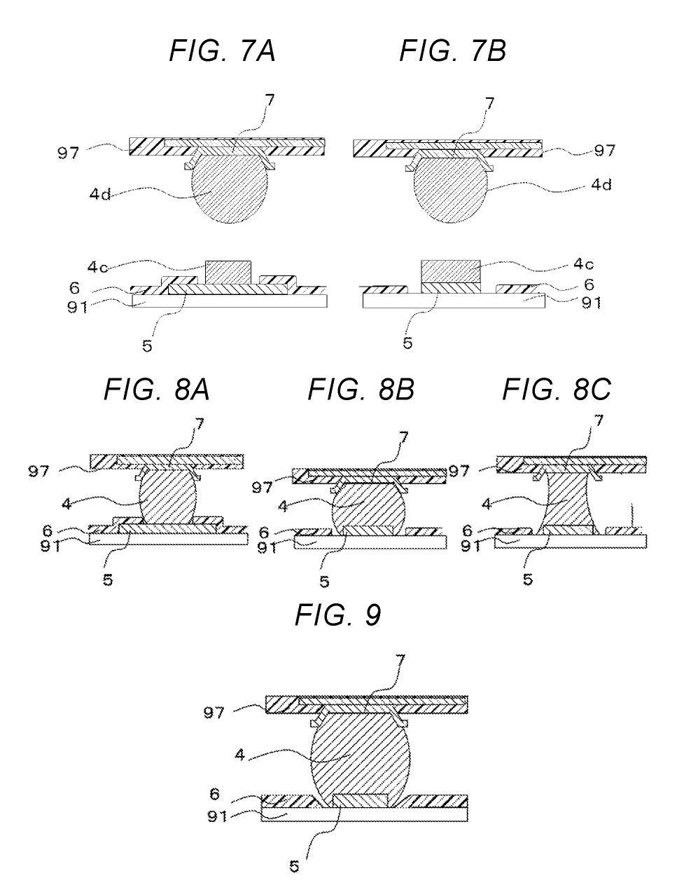

Next, a method of forming the solder bumps 4 of the semiconductor chip 10 according to the present embodiment will be described. FIGS. 7A and 7B are cross-sectional views illustrating a portion of the semiconductor chip 10 and a portion of the mounting board 91 before bonding. FIG. 7A illustrates the cross-sectional view of an SMD, FIG. 7B illustrates the cross-sectional view of an NSMD, and the same is true of the following description.

As illustrated in FIGS. 7A. and. 7B, the lands 5 are formed on the mounting board 91. Next, at the SMD, as illustrated in FIG. 7A, the solder resist layer 6 is formed so as to cover the outer circumferential edge portions of the land 5, and at the NSMD, as illustrated in FIG. 7B, the edge of the opening of the solder resist layer 6 is formed at a distance from the land 5.

Next, a metal mask (not illustrated) having openings at the regions corresponding to the lands 5 is formed on the solder resist 6, and paste solder 4c is applied in the openings. The openings of the metal mask are formed such that the diameters of the openings around the NSMD are larger than the diameters of the openings over the SMD. Therefore, the amount of the paste solder 4c applied to the NSMD is greater than the amount of the paste solder 4c applied to the SMD. After applying the paste solder 4c, the metal mask is removed.

Next, positioning is performed such that the solder balls 4d formed on the lower surface of the semiconductor chip 10 are positioned on the applied paste solder 4c locations, and the solder balls 4d are respectively bonded to the paste solder 4c locations. The solder balls 4d are formed in advance such that the sizes and the heights thereof are all substantially uniform. The paste solder 4c and the respective solder balls 4d are melted and cooled by heating, and thus the paste solders 4c and the solder balls 4d are fused together, thereby forming the solder bumps 4. As described above, the solder bumps 4 according to the present embodiment are formed.

The reason why the amount of the paste solders 4c in the NSMD is increased will be described below.

FIGS. 8A and 8B illustrate comparative examples in a case where the amounts of the paste solder 4c in the SMD and the NSMD are set to the same level. As illustrated in FIG. 8B, in the NSMD, the solder bump 4 is formed so as to cover the side surfaces of the land 5, and the solder bail 4d has the substantially same size in the SMD and the NSMD. Thus, in the NSMD, the stand-off height of the solder bump 4 formed on the land 5 is lower than that of the solder bump 4 in the SMD. The stand-off height is the distance between the mounting surface (the first surface 91a) of the mounting board 91 and the lower surface of the semiconductor component (here, the power supply circuit 97). When the stand-off height becomes high, tolerance to the shear stress due to temperature change or the like increases. However, in this state, when the NSMD are formed for the solder bumps 4 at the four corners on the mounting board 91 and the SMD are formed for the other solder bumps 4, as illustrated in FIG. 8C, the stand-off height of the NSMD increases to the same level as that of the SMD based on the stand-off height of the SMD, but the width of the NSMD becomes thinner by the increased amount in height. When the width of the NSMD becomes thinner, bonding force between the mounting board 91 and the NSMD becomes weaker, and tolerance to the shear stress becomes less. Therefore, in the NSMD, the amount of the paste solder 4c is increased, and the cross-sectional area in the horizontal direction parallel to the mounting board 91 is increased to have substantially the same cross-sectional area as that of NSMD illustrated in FIG. 8B.

According to the semiconductor device 100 of the present embodiment, both SMDs and NSMDs are used for the solder bumps 4, and thus the combination of solder bumps 4 are strong against the shear stress compared to the case where SMDs are used for all the solder bumps 4. Further, it is possible to reduce the possibility that the bonding force between the NSMD and the mounting board 91 becomes weak, by increasing the amount of the paste solder 4c in the NSMD.

Furthermore, in the component having a narrow pitch width on the mounting board 91, among the solder bumps 4 in the mounting region, NSMDs are used for the solder bumps 4 at the four corners and the solder bumps 4 adjacent thereto, and SMDs are used for the other solder bumps 4. Thus, it is possible to provide a semiconductor device that can have a strong tolerance to shear stress and reduced occurrence of a solder bridge.

### Second Embodiment

Next, the semiconductor device 100 according to a second embodiment viii be described with reference to FIG. 9. The configuration of the semiconductor device 100 according to the second embodiment is the same as that of the semiconductor device 100 according to the first embodiment. In the second embodiment, in the NSMD as the solder bump 4 of the semiconductor chip 10 illustrated in the first embodiment, the side surface of the opening of the solder resist layer 6 is changed. Here, the side surface is a surface that faces the land 5 and forms the perimeter of the opening of the solder resist layer 6, and which is different from the surface which is substantially parallel to the first surface 91a of the mounting board 91.

FIG. 9 is a cross-sectional view of an NSMD used for the semiconductor chip 10 mounted on the semiconductor device 100 according to the present embodiment. As illustrated in FIG. 9, in the present embodiment, the diameter of the opening of the solder resist layer 6 on the semiconductor chip 10 side thereof is larger than the diameter of the opening of the solder resist layer 6 on the mounting board 91 side thereof. That is, as illustrated in FIG. 9, an angle θ between the first surface 91a of the mounting board 91 and the side surface of the opening of the solder resist 6 is smaller than 90°. That is, the side surface of the opening of the solder resist 6 is, for example, an inclined surface. In this case, although θ satisfies, for example, 30≤θ≤80, θ is not limited thereto.

The NSMD has such a shape, and thus it is possible to reduce the risk of occurrence of a crack in the solder bump 4 due to the contact of the solder resist layer 6 to the solder bump 4, without enlarging the size of the opening of the solder resist layer 6.

The shape of the wall of the opening in the solder resist layer 6 according to the present embodiment is not limited to the NSMD, and can be applied to the SMD. Even in the SMD, the same effect as that of the NSMD can be obtained.

According to the semiconductor device 100 of the present embodiment, the side surface of the opening of the solder resist layer 6 is an inclined surface, and thus it is possible to reduce the possibility of occurrence of a crack in the solder bump 4.

### Third Embodiment

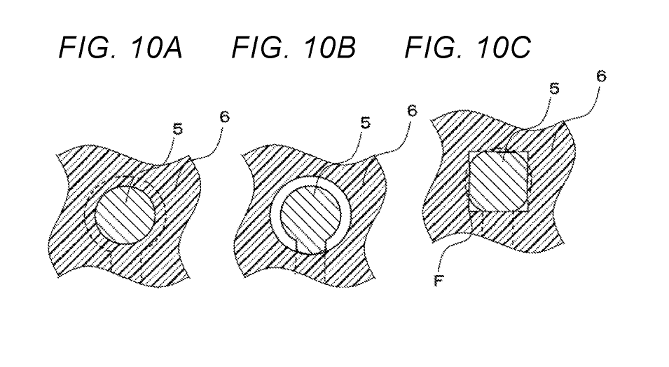

Next, the semiconductor device 100 according to a third embodiment will be described with reference to FIGS. 10A to 10C. In the third embodiment, the solder bumps 4 having a structure different from the structures of the SMD and the NSMD are used at the four corners of the semiconductor chip 10, as compared to the first and second embodiments.

FIGS. 10A to 10C are plan views respectively illustrating the structures of one land 5 and the solder resist layer 6 in the mounting region of the power supply circuit 97 on the mounting board 91 of the semiconductor device 100 according to the present embodiment. That is, FIGS. 10A to 10C illustrate the configurations on the mounting board 91 before the paste solder 4c is applied.

FIG. 10A. illustrates the SMD illustrated in the first embodiment, FIG. 10B illustrates the NSMD illustrated an the first embodiment, and FIG. 10C illustrates the structure according to the third embodiment. Although the solder resist layer 6 is illustrated around only the one land 5, actually, there are the plurality of the lands 5 and the solder resist layer 6 also extends over a wide range. The broken line portion illustrates the outer shape of the land 5 that is positioned on the bottom of the solder resist layer 6.

As illustrated in FIG. 10C, in the structures of the land 5 and the solder resist layer 6 according to the present embodiment, the opening of the solder resist layer 6 has a rectangular shape and the land 5 has a circular shape. The opening of the solder resist layer 6 is formed such that at least some of the four sides of the opening, which form a substantially square shape, cover the outer circumferential edge portions of the land 5 as in the SMD Illustrated in FIG. 10A. On the other hand, the four vertexes (corners) F are formed at a distance from the land 5 as in the NSMD. That is, the region formed by the vertexes of the opening is formed such that the solder bump 4 covers the side surfaces of the land 5. Therefore, the bonding force between the solder bump 4 and the mounting board 91 is increased, and thus the solder bumps 4 are strong against shear stress.

Further, in the SMD according to the present embodiment, since the width of the opening in a direction parallel to the mounting board 91 is smaller than that of the opening for an NSMD, the frequency of occurrence of a bridge is lower than that in the NSMD.

According to the semiconductor device 100 of the present embodiment, the openings in the solder resist layer 6 at the four corners of the semiconductor chip 10 on the mounting board 91 have a rectangular shape, and thus it is possible to provide a semiconductor device that can maintain tolerance to shear stress and also reduce the frequency of occurrence of a solder bridge.

The structure illustrated in the third embodiment is not limited to the four corners of the mounting region, and can be used for all the solder bumps 4 in the mounting region.

Although an example in which the semiconductor device 100 illustrated in the first to third embodiments is applied to the SSD is described, the semiconductor device 100 can also be applied to other mounting structures.

In the semiconductor device 100 illustrated in the first to third embodiments, the electronic components and the like mounted on the mounting board 91 have the structure illustrated in the first to third embodiments, and thus it is possible to adjust the heat quantity radiated from the SSD. This is because, for example, when the structure illustrated in the first to third embodiments is used in the mounting of the electronic components, the cross-sectional area of the solder bump 4 in a direction parallel to the first surface of the mounting board 91 can be increased, compared to the case where all the solder bumps 4 are SMDs. When the cross-sectional area of the solder bump 4 is increased, the heat conductivity of the solder bump 4 increases. Further, in the semiconductor device 100 according to the present embodiment, heat is released from the ground patterns of the electronic components and the like to the ground pattern of the semiconductor device 100. The ground terminal of the power supply circuit is designed to have a wide pattern area, and is suitable as a path for dissipating heat. Therefore, the NSMD or the solder bump that is set as the ground terminal among the solder bumps according to the third embodiment has a high heat conductivity, and other solder bumps have a low heat conductivity. As a result, it is possible to adjust the heat quantity radiated from the SSD.

While certain embodiments have been described, these embodiments have been presented by way of example only, and are not intended to limit the scope of the inventions. For example, in the above description, although an example in which the semiconductor chip 10 is applied to the power supply circuit 97 is described, the semiconductor chip 10 may be applied to a CSP other than the power supply circuit 97. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a board having a first surface;
a solder resist layer on the first surface, the solder resist layer comprising a first opening and a second opening;
a first electrode on the first surface and having a side surface exposed in the first opening, the first electrode electrically connected to the board;
a second electrode, having an outer perimeter, on the first surface, wherein the second electrode electrically connected to the board and at least a portion of the outer perimeter of the second electrode covered by the solder resist layer;
a first solder hump on the first electrode, the first solder bump covering the side surface of the first electrode;
a second solder bump on the second electrode; and
a semiconductor chip comprising a second surface facing the first surface, the second surface comprising a first region and a second region, wherein a third electrode in the first region of the semiconductor chip is electrically connected to the first solder bump, and a fourth electrode in the second region of the semiconductor chip is electrically connected to the second solder bump, wherein
the first opening has a non-circular perimeter.

2. The semiconductor device according to claim 1, wherein
a first portion of the first electrode is covered by the solder resist layer; and
a second portion of the first electrode is not covered by the solder resist layer

3. The semiconductor device according to claim 1, wherein
the second surface has a geometric center; and
the first solder bump is outside the range of a distance from the geometric center of the second surface.

4. The semiconductor device according to claim 1, wherein
the perimeter of the first opening has a rectangular shape having tour sides and four vertices;
a portion of each of the four sides of the first opening is on the first electrode; and
the four vertices of the first opening are spaced from the first electrode.

5. The semiconductor device according to claim 1, wherein
the second opening comprises a rectangular shape having four sides and four vertices;
a portion of each of the four sides of the second opening is on the second electrode; and
the four vertices of the second opening are spaced from the second electrode.

6. The semiconductor device according to claim 1, wherein
a plurality of first solder bumps and plurality of second solder bumps extend between the second surface and the first surface; and
the first and the second solder bumps are arranged in a lattice pattern.

7. The semiconductor device according to claim 1, wherein the maximum cross-sectional area of the first solder bump in a direction parallel to the first surface is larger than the maximum cross-sectional area of the second solder bump in a direction parallel to the first surface.

8. A semiconductor device, comprising:
a board having a first surface with a central region and a perimeter region;
a semiconductor chip having a second surface with a central region and a perimeter region, facing the first surface, wherein the board and the semiconductor chip have different thermal expansion properties;
a solder resist layer on the first surface, the solder resist layer having a first opening therethrough in the central region and a second opening therethrough in the perimeter region;
a first electrode on the first surface in the central region and electrically connected to the board, at least a portion thereof exposed in the first opening and a portion thereof covered by the solder resist layer;
a second electrode, having an outer circumferential surface, on the first surface in the perimeter region, wherein the second electrode is electrically connected to the board, and at least a portion of the outer circumferential surface thereof is spaced from the solder resist layer;
a first solder bump on the first electrode; and
a second solder bump on the second electrode, at least a portion of the outer circumferential surface of the second electrode covered by the second solder bump, wherein
a third electrode in the central region of the semiconductor chip is electrically connected to the first solder bump, and a fourth electrode in the perimeter region of the semiconductor chip is electrically connected to the second solder bump;
the second electrode has a circular perimeter;
the second opening has a non-circular profile having at least three sides and three vertices; and
the solder resist layer overlies a portion of the second electrode and the vertices of the second opening are spaced from the second electrode.

9. The semiconductor device according to claim 8, wherein the first and the second solder bumps have a maximum cross section and toe maximum cross section of the second solder bump is larger than the maximum cross section of the first solder bump.

10. The semiconductor device according to claim 8, wherein
a plurality of first electrodes having the solder resist layer overlying the first electrode around, and inwardly of, the perimeter thereof, are in the central region; and
a plurality of second electrodes having the solder resist layer spaced from the second electrode entirely around the perimeter thereof are in the perimeter region.

11. The semiconductor device according to claim 8, wherein the plurality of first electrodes are greater in number that the plurality of second electrodes.

12. The semiconductor device according to claim 8, wherein
the semiconductor chip and the board have a plurality of sides and a plurality of vertices equal in number to the plurality of sides; and
the perimeter region includes a portion of the first and second surfaces adjacent to the vertices.

13. The semiconductor device according to claim 8, wherein the second solder bump extends over the outer circumferential surface of the second electrode about the perimeter thereof, and is spaced from the solder resist layer about the perimeter thereof.

14. A method of manufacturing a semiconductor device, comprising:
providing a board having a first surface;
providing a solder resist layer on the first surface, the solder resist layer comprising a plurality of first openings and a plurality of second openings;
providing a plurality of first electrodes on the first surface, at least a portion of each first electrode exposed in a respective one of the first openings and electrically connected to the board;
providing a plurality of second electrodes, each having an outer circumferential portion, on the first surface, wherein at least a portion of each is exposed through a respective one of the second openings, the second electrode electrically connected to the board and at least a portion of the outer circumferential portion of each of the second electrodes is covered by the solder resist layer;
providing a first volume of solder paste on each of the first electrodes;
providing a second volume of solder paste, greater than the first volume, on each of the second electrodes;
providing a semiconductor chip having a second surface and a plurality of solder bails on the second surface;
contacting individual ones of the solder balls on the second surface with the volume of solder paste on individual ones of the first and second electrodes;
heating the solder paste and solder balls to the melting temperature thereof and melting the solder ball and solder paste at each of the first and second electrodes to cause them to form a melted volume; and
allowing the melted volume to cool and form a solder bump interconnecting the semiconductor chip and the board.

15. The method of claim 14, wherein the solder bumps formed on the second electrodes have a larger maximum cross sectional area than the maximum cross sectional area of the solder bumps formed on the first electrodes.
